(19) United States
(12) Patent Application Publication
(10) Pub. No.: US 2013/0119397 A1
(43) Pub. Date: May 16, 2013

(54) NITRIDE-BASED HETEROJUCTION SEMICONDUCTOR DEVICE AND METHOD FOR MANUFACUTRING THE SAME

(71) Applicants: Youngshin Eum, Seoul (KR); Taehoon Jang, Seoul (KR)

(72) Inventors: Youngshin Eum, Seoul (KR); Taehoon Jang, Seoul (KR)

(21) Appl. No.: 13/676,768

(22) Filed: Nov. 14, 2012

(30) Foreign Application Priority Data
Nov. 15, 2011 (KR) 10-2011-0118823

(51) Int. Cl. H01L 29/20; H01L 29/78

(52) U.S. Cl. CPC H01L 29/2003; H01L 29/78
USPC 257/76; 438/299

(57) ABSTRACT

Disclosed is a semiconductor device. More specifically, disclosed are a nitride-based heterojunction semiconductor device and a method for manufacturing the same. The nitride-based heterojunction semiconductor device includes a first drain electrode, a conductive semiconductor layer including a nitride-based semiconductor disposed on the first drain electrode, a channel layer disposed on the conductive semiconductor layer, a barrier layer disposed on the channel layer, a source electrode and a second drain electrode spaced from each other on the barrier layer, and a gate electrode disposed between the source electrode and the second drain electrode.

Pursuant to 35 U.S.C. §119(a), this application claims the benefit of Korean Patent Application No. 10-2011-0118823, filed on Nov. 15, 2011, which is hereby incorporated by reference as if fully set forth herein.

### BACKGROUND OF THE INVENTION

1. Field of the Invention

The present invention relates to a semiconductor device. More specifically, the present invention relates to a nitride-based heterojunction semiconductor device and a method for manufacturing the same.

2. Discussion of the Related Art

A nitride semiconductor is a wide band gap compound semiconductor which emits light ranging from visible to ultraviolet. Celadon green laser diodes and blue light-emitting diodes have been developed and are widely used for optical pickup devices, traffic lights, public displays, liquid crystal backlights, and lightings. In recent years, nitride semiconductors have received attention due to high critical electric field and low temperature-resistance characteristics and are thus advanced-researched as materials for next-generation semiconductor devices.

MOSFET and IGBT that are high power elements as recent mainstreams are competing with each other and devices such as HEMT and MOSFET using the nitride semiconductors are being researched. Among these, HEMT is used for high-frequency communication elements utilizing high electron mobility.

### SUMMARY OF THE INVENTION

Accordingly, the present invention is directed to a nitride-based heterojunction semiconductor device and a method for manufacturing the same that substantially obviate one or more problems due to limitations and disadvantages of the related art.

It is one object of the present invention to provide a nitride-based heterojunction semiconductor device in which an electric field in a device is reduced and an area of electrodes is maximized to increase current, and the semiconductor device satisfies one or more high breakdown voltage characteristics and a method for manufacturing the same.

In accordance with one aspect of the present invention, provided is a nitride-based heterojunction semiconductor device including: a first drain electrode; a conductive semiconductor layer including a nitride-based semiconductor disposed on the first drain electrode; a channel layer disposed on the conductive semiconductor layer; a barrier layer disposed on the channel layer; a source electrode and a second drain electrode spaced from each other on the barrier layer; and a gate electrode disposed between the source electrode and the second drain electrode.

In accordance with another aspect of the present invention, provided is a nitride-based heterojunction semiconductor device including: a conductive semiconductor layer including a nitride-based semiconductor having a first surface and a second surface; a first drain electrode disposed on the first surface of the conductive semiconductor layer; a channel layer disposed on the second surface of the conductive semiconductor layer; a barrier layer disposed on the channel layer; a source electrode and a second drain electrode spaced from each other on the barrier layer; and a gate electrode between the source electrode and the second drain electrode.

In accordance with another aspect of the present invention, provided is a method for manufacturing a nitride-based heterojunction semiconductor device including: forming a conductive semiconductor layer including a nitride-based semiconductor having a first surface and a second surface on a substrate; forming a first drain electrode in at least one part on the first surface of the conductive semiconductor layer; forming a channel layer on the conductive semiconductor layer and the current barrier layer; forming a barrier layer on the channel layer; forming a source electrode, a first drain electrode and a gate electrode on the barrier layer such that the source electrode, the first drain electrode and the gate electrode are spaced from one another; and forming a second drain electrode on the second surface of the conductive semiconductor layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide further understanding of the disclosure and are incorporated in and constitute a part of this application, illustrate embodiments of the disclosure and together with the description serve to explain the principle of the disclosure. In the drawings:

FIG. 1 is a sectional view illustrating an example of a nitride-based heterojunction semiconductor device;

FIGS. 2 to 6 are sectional views illustrating a method for a nitride-based heterojunction semiconductor device;

FIG. 2 is a sectional view illustrating formation of an n-type semiconductor layer on a substrate;

FIG. 3 is a sectional view illustrating formation of a current barrier layer;

FIG. 4 is a sectional view illustrating a state in which the current barrier layer is formed;

FIG. 5 is a sectional view illustrating formation of a channel layer and a barrier layer; and

FIG. 6 is a sectional view illustrating formation of an electrode.

### DETAILED DESCRIPTION OF THE INVENTION

Reference will now be made in detail to the specific embodiments of the present invention, examples of which are illustrated in the accompanying drawings.

However, the present invention allows for various modifications and variations and specific embodiments thereof are described in the drawings and will be described in detail. The present invention should not be construed as limited to the embodiments set forth herein and includes modifications, variations, equivalents, and substitutions compliant with the spirit or scope of the present invention defined by the appended claims.

It will be understood that when an element such as a layer, area, or substrate is referred to as being “on” another element, it can be directly on the element, or one or more intervening elements may also be present.

Also, it will be understood that although terms such as “first” and “second” may be used herein to describe elements, components, areas, layers and/or regions, the elements, components, areas, layers and/or regions should not be limited by these terms.

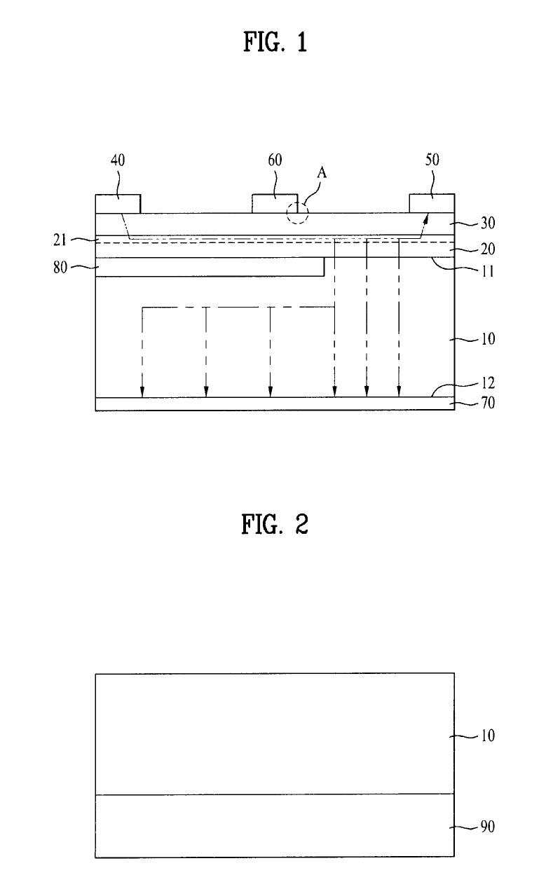

As shown in FIG. 1, the nitride-based heterojunction semiconductor device has a configuration in which a current barrier layer 80 is disposed in one part on a first surface 11 of a first-type conductive semiconductor layer 10. Here, the first-type conductive semiconductor layer 10 is, for example, an n-type semiconductor and may be a nitride-based semiconductor comprising gallium nitride (GaN). Hereinafter, an example in which the first-type conductive semiconductor layer 10 is an n-type semiconductor layer 10 will be described.

As such, the n-type semiconductor layer 10 is used since low resistance is advantageous for smooth current flow and an electrode (second drain electrode 70) may be disposed thereunder.

A channel layer 20, provided thereon with a 2-dimensional electron gas (2DEG) layer 21, is disposed on the n-type semiconductor layer 10 and the current barrier layer 80.

A barrier layer 30 is disposed on the channel layer 20. The channel layer 20 may comprise a gallium nitride (GaN) semiconductor and the barrier layer 30 may comprise an aluminum gallium nitride (AlGaN) material. In this case, the content of aluminum (Al) present in AlGaN may be 10% to 50% with respect to gallium (Ga) (AlₓGa₁₋ₓN (0.1≦x≦0.5)).

The 2DEG layer 21 is a considerably thin part which is disposed in a region where the channel layer 20 contacts the barrier layer 30 and may have a thickness of about 1 nm.

A source electrode 40 and a first drain electrode are disposed on the barrier layer 30. The source electrode 40 and the first drain electrode 50 are disposed at opposite positions, that is, at opposite ends on the barrier layer 30. The source electrode 40 and the first drain electrode 50 may ohmic-contact the barrier layer 30.

The source electrode 40 and the first drain electrode 50 may comprise at least one of Ti, Al and Au. For example, the source electrode 40 and the first drain electrode 50 constitute a multi-layer such as Ti/Al/Ti/Au in which Ti/Al/Ti/Au has a thickness of 30 nm/100 nm/20 nm/200 nm, repectively.

A gate electrode 60 is disposed between the source electrode 40 and the first drain electrode 50. A second drain electrode 70 may be disposed on a second surface 12, i.e., a rear surface of the n-type semiconductor layer 10.

As shown in the drawing, an area of the second drain electrode 70 disposed under the n-type semiconductor layer 10 may be the same as an area of the n-type semiconductor layer 10. If necessary, the area of the second drain electrode 70 may be smaller than the area of the n-type semiconductor layer 10.

Such a second drain electrode 70 may have a vertical-type semiconductor device structure, enabling current to flow from the source electrode 40 through the n-type semiconductor layer 10 to a lower part of the device.

Meanwhile, as described above, a current barrier layer 80 comprising a high-resistance material may be disposed in at least one part between the n-type semiconductor layer 10 and the barrier layer 20.

Such a current barrier layer 80 prevents a phenomenon in which leakage current generated from the n-type semiconductor layer 10 makes turn-off of the device difficult.

The current barrier layer 80 may be disposed at least in a lower part of the gate electrode 60. The current barrier layer 80 is disposed at least in a lower part of the position “A”.

The current barrier layer 80 may be evenly distributed without concentrating at the gate electrode 60, and the source electrode 40 extends to the lower part of the gate electrode 60.

When the current barrier layer 80 is not formed, current may be concentrated at one side of the gate electrode 60, that is, mainly at the position “A”. However, as described above, the current barrier layer 80 is disposed such that it covers the entire surface of the gate electrode 60, current from the source electrode 40 is not concentrated at the gate electrode 60 and flows through the n-type semiconductor layer 10 to the first drain electrode 50 and the second drain electrode 70.

The current barrier layer 80 may be an insulating layer and is for example a high-resistance gallium nitride semiconductor layer. That is, the n-type semiconductor layer 10 may be an insulating layer.

The semiconductor device has high electron mobility and high critical electric field and, in particular, is useful as a high breakdown-voltage device that withstands a high voltage.

In a common latteral device, a source electrode, a drain electrode and a gate electrode are provided at only one surface. Accordingly, the size of the electrode determines a size of the device. However, the distance between electrodes should be secured in order to realize a high breakdown-voltage device, and areas of the source electrode and the drain electrode that require a relatively large area may be reduced in order to reduce a device area.

However, the structure as described above has advantages of vertical devices, thus increasing areas of the drain electrodes 50 and 70 and reducing an electric field.

That is, current flows from the source electrode 40 to the first drain electrode 50 through the 2DEG layer 21 in a horizontal direction, and as shown in an arrow of FIG. 1, current flows through the n-type semiconductor layer 10 toward the second drain electrode 70. Accordingly, the total device area can be reduced due to increase in current.

Furthermore, based on the current flow and configuration of the current barrier layer 80, an electric field that may be concentrated on the gate electrode 60 is distributed toward the n-type semiconductor layer 10 and breakdown voltage is thus disadvantageously increased.

Also, devices that can more efficiently withstand a high voltage under the same area conditions can be realized. Since the area of the electrode is related to an amount of current, devices having a higher current relative to the total area of devices can be manufactured.

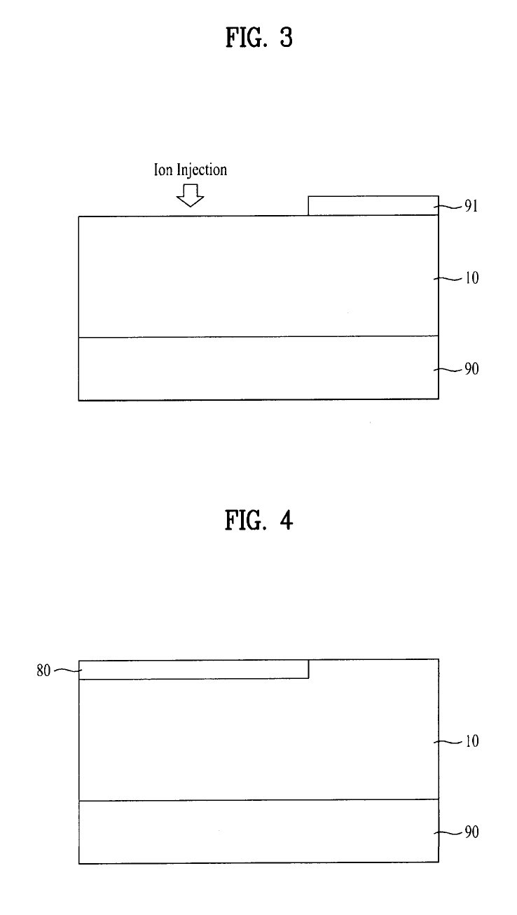

Hereinafter, a method for manufacturing a nitride-based heterojunction semiconductor device will be described with reference to FIGS. 2 to 6.

First, as shown in FIG. 2, a substrate 90 on which the n-type semiconductor layer 10 is grown is prepared. The substrate 90 may be a sapphire, silicon (Si), silicon carbide (SiC), or gallium nitride (GaN) substrate.

The n-type semiconductor layer 10 may be a gallium nitride (GaN) semiconductor and may be formed by metal-organic chemical vapor deposition (MOCVD). Growth using MOCVD is carried out by synthesizing TMGa as a raw material of Ga, and NH₃ a raw material of N in a reactor at a high temperature to grow a thin film.

In some cases, in order to form the n-type semiconductor layer 10, an additional buffer layer (not shown) may be formed on the substrate 90.

In the growth of the n-type semiconductor layer 10, an n-type dopant may be added in order to impart n-type conductivity to the n-type semiconductor layer 10. The n-type dopant may be Si and a raw material such as SiH₄ or SiH₆ may be used.

Hereinafter, a mask layer 91 is formed on the n-type semiconductor layer 10. The mask layer 91 may be formed in a part excluding a region where the current barrier layer 80 is formed. The position of the current barrier layer 80 is described above.

Such a mask layer 91 may be a photoresist or an insulating layer such as SiO₂ or SiNₓ.

Next, the n-type semiconductor layer 10 is insulated through an ion injection process to form a high resistance layer and thereby obtain a current barrier layer 80.

Such an ion injection process may utilize ions such as Mg, N, B, P, or Ar capable of insulating the n-type GaN semiconductor.

Next, when the mask layer 91 is removed using a washing or etching process, the current barrier layer 80 is formed in a region excluding the mask layer 91, as shown in FIG. 4.

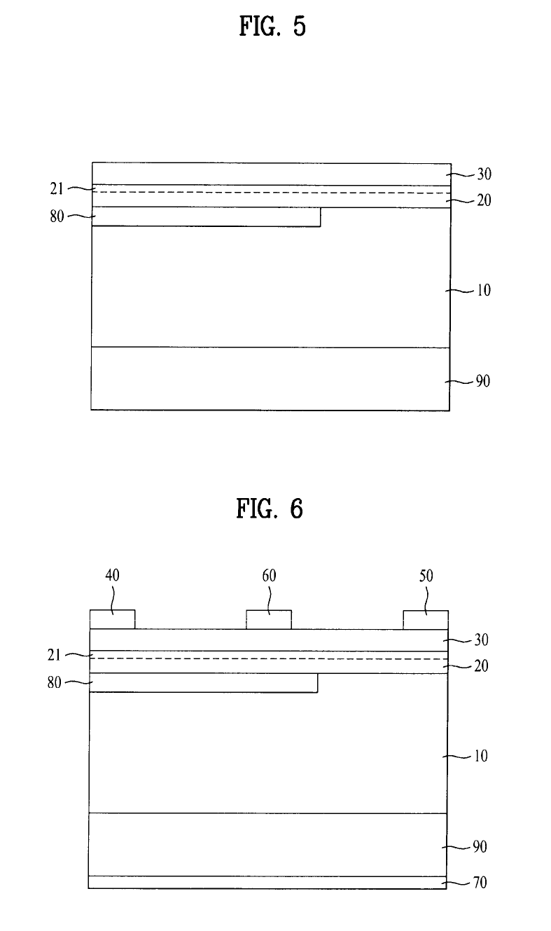

Next, as shown in FIG. 5, a channel layer 20 constituting the 2DEG layer 21b is formed on the current barrier layer 80 and the n-type semiconductor layer 10, and a barrier layer 30 is formed on the channel layer 20.

The channel layer 20 may have a thickness of 0.01 to 0.05 μm, beneficially, about 0.05 to about 0.2 μm.

The barrier layer 30 may be formed of an aluminum gallium nitride (AlGaN) semiconductor. In this case, the content of aluminum (Al) may be 1% to 100% with respect to gallium (Ga) and may be about 10% to about 50% (AlₓGa₁₋ₓN (in which 0.1≦x≦0.5).

Also, the barrier layer 30 has a thickness of about 100 nm or less, beneficially about 0 to about 10 nm.

Next, as shown in FIG. 6, the source electrode 40, the first drain electrode 50, the gate electrode 60 and the second drain electrode 70 may be spaced from one another.

In this case, the source electrode 40 and the first drain electrode 50 are disposed at opposite positions on the barrier layer 30. The gate electrode 60 may be manufactured between the source electrode 40 and the first drain electrode 50.

FIG. 6 illustrates a structure in which a second drain electrode 70 is formed under a growth substrate 90 provided with the n-type semiconductor layer 10. When the growth substrate 90 is a conductive substrate, the second drain electrode 70 may be formed on the lower surface of the substrate 90.

Also, if desired, the substrate 90 is removed and the second drain electrode 70 is formed. In this case, a structure shown in FIG. 1 is formed. For example, when the substrate 90 is an insulating substrate such as sapphire or has insufficient conductivity, the substrate 90 is removed. In this case, the second drain electrode 70 may be formed on the exposed n-type semiconductor layer 10.

As described above, the source electrode 40, the first drain electrode 50 and the second drain electrode 70 form an ohmic contact using at least one of Ti, Al and Au.

That is, the source electrode 40, the first drain electrode 50 and the second drain electrode 70 are deposited using E-beam deposition equipment to form a multi-layer structure such as Ti/Al/Ti/Au and a pattern can be formed through a lift-off process. Also, the multi-layer structure may have a thickness of 30 nm/100 nm/20 nm/200 nm, respectively.

The gate electrode 60 may be formed using at least an electrode material having a high work function such as Ti, Al or Ni.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A nitride-based heterojunction semiconductor device comprising:
a first drain electrode;
a conductive semiconductor layer comprising a nitride-based semiconductor disposed on the first drain electrode;
a channel layer disposed on the conductive semiconductor layer;
a barrier layer disposed on the channel layer;
a source electrode and a second drain electrode spaced from each other on the barrier layer; and
a gate electrode disposed between the source electrode and the second drain electrode.

2. The nitride-based heterojunction semiconductor device according to claim 1, further comprising:
a current barrier layer disposed between the conductive semiconductor layer and the channel layer,
wherein the current barrier layer has an opening at least at the side of the second drain electrode.

3. The nitride-based heterojunction semiconductor device according to claim 2, wherein the current barrier layer is disposed at least at a lower side of the gate electrode.

4. The nitride-based heterojunction semiconductor device according to claim 2, wherein the current barrier layer extends from a lower side of the source electrode to the lower side of the gate electrode.

5. The nitride-based heterojunction semiconductor device according to claim 1, wherein the current barrier layer comprises high-resistance gallium nitride.

6. The nitride-based heterojunction semiconductor device according to claim 1, wherein the conductive semiconductor layer comprises n-type gallium nitride.

7. The nitride-based heterojunction semiconductor device according to claim 1, wherein an area of the first drain electrode is substantially equivalent to an area of the conductive semiconductor layer.

8. The nitride-based heterojunction semiconductor device according to claim 1, wherein the first drain electrode and the second drain electrode are disposed at opposite sides of the conductive semiconductor layer.

9. The nitride-based heterojunction semiconductor device according to claim 1, wherein the source electrode and the first and second drain electrodes comprise at least one of Ti, Al and Au.

10. A nitride-based heterojunction semiconductor device comprising:
a conductive semiconductor layer comprising a nitride-based semiconductor having a first surface and a second surface;
a first drain electrode disposed on the first surface of the conductive semiconductor layer;
a channel layer disposed on the second surface of the conductive semiconductor layer;
a barrier layer disposed on the channel layer;
a source electrode and a second drain electrode spaced from each other on the barrier layer; and
a gate electrode between the source electrode and the second drain electrode.

11. The nitride-based heterojunction semiconductor device according to claim 10, further comprising:
a current barrier layer disposed in at least one part between the conductive semiconductor layer and the channel layer.

12. The nitride-based heterojunction semiconductor device according to claim 11, wherein the current barrier layer is disposed at least at a lower side of the gate electrode.

13. The nitride-based heterojunction semiconductor device according to claim 11, wherein the current barrier layer extends from a lower side of the source electrode to the lower side of the gate electrode.

14. The nitride-based heterojunction semiconductor device according to claim 11, wherein the current barrier layer comprises high-resistance gallium nitride.

15. The nitride-based heterojunction semiconductor device according to claim 10, wherein the conductive semiconductor layer directly contacts the channel layer in one region of the lower part of the second drain electrode.

16. The nitride-based heterojunction semiconductor device according to claim 10, wherein the first drain electrode and the second drain electrode are disposed at opposite sides of the conductive semiconductor layer.

17. A method for manufacturing a nitride-based heterojunction semiconductor device comprising:
forming a conductive semiconductor layer comprising a nitride-based semiconductor having a first surface and a second surface on a substrate;
forming a first drain electrode in at least one part on the first surface of the conductive semiconductor layer;
forming a channel layer on the conductive semiconductor layer and the current barrier layer;
forming a barrier layer on the channel layer;
forming a source electrode, a first drain electrode and a gate electrode on the barrier layer such that the source electrode, the first drain electrode and the gate electrode are spaced from one another; and
forming a second drain electrode on the second surface of the conductive semiconductor layer.

18. The method according to claim 17, wherein the forming the current barrier layer comprises:
forming a mask layer on the conductive semiconductor layer; and
injecting ions capable of insulating the conductive semiconductor layer into the conductive semiconductor layer.

19. The method according to claim 17, wherein the current barrier layer extends from a lower part of the source electrode to a lower part of the gate electrode.

20. The method according to claim 17, further comprising: removing the substrate before forming the second drain electrode.
